(19) United States
(12) Patent Application Publication
(10) Pub. No.: US 2008/0124847 A1
(43) Pub. Date: May 29, 2008

(54) Reducing Crystal Defects from Hybrid Orientation Technology During Semiconductor Manufacture

(75) Inventor: Gaku Sudo, Yokohama (JP)

Correspondence Address: BANNER & WITCOFF, LTD., 1100 13th STREET, N.W., SUITE 1200, WASHINGTON, DC, 20005-4051, US

(73) Assignee: TOSHIBA AMERICA ELECTRONIC COMPONENTS, INC., Irvine, CA (US)

(21) Appl. No.: 11/462,424

(22) Filed: Aug. 4, 2006

(51) Int. Cl. H01L 21/84

(52) U.S. Cl. 438/152; 257/E21.7

(57) ABSTRACT

Aspects of the present disclosure are directed to reducing strain in at least a portion of a bulk silicon region formed in a silicon-on-insulator (SOI) wafer using a hybrid orientation technology (HOT) process. A trench is formed having a sidewall liner. The liner is recessed prior to oxidation of the bulk silicon region upper surface as part of the HOT process. Recessing the trench liner provides room for the silicon to laterally expand during this oxidation. The trench liner may be recessed by various amounts, such as to approximately the bottom of a hard mask layer, or approximately halfway to the bottom of the hard mask layer, or anywhere in between. The trench liner may even be recessed more deeply than the bottom of the hard mask layer, such as down to or below the upper surface of the upper silicon layer of the surrounding SOI wafer.

### BACKGROUND

Hybrid orientation technology (HOT) has been recently developed as a way to enhance the performance of field-effect transistors (FETs). HOT typically involves epitaxially growing a local bulk silicon region in a trench embedded in a traditional silicon-on-insulator (SOI) wafer, and forming the FET in and on the bulk silicon layer. HOT allows FETs to be placed in silicon regions having the optimal crystal surface orientation, regardless of the surface orientation of the silicon in the surrounding SOI. For P-type FETs (PFETs), the ideal surface orientation is (110), and for N-type FETs (NFETs), the ideal surface orientation is (100). By placing a FET in silicon having the ideal surface orientation, electron or hole mobility, and thus FET performance, is increased.

After epitaxially growing the bulk silicon region, the upper surface of the bulk silicon region is lowered using chemical-mechanical polishing (CMP) down to the level of the hard mask. Then, to further lower the surface of the bulk silicon region to match the upper surface level of the surrounding SOI region, the bulk silicon region is oxidized and the upper oxidized layer is etched away. The oxidation step also increases the volume of the oxidized silicon, thereby producing a large amount of strain on the bulk silicon region. While some strain is desirable for FET enhancement, the strain can be so large that crystal defects are introduced in the bulk silicon region. The reason for this large strain is that, the bulk silicon region is free to expand upward during oxidation, but it is prevented from growing laterally by the relatively stiff oxide layer lining the trench.

### SUMMARY

It is desirable to produce a bulk silicon region using a modified hybrid orientation technology (HOT) process that has fewer, or even a total lack of, crystal defects caused by strain during bulk silicon region oxidation.

Accordingly, aspects of the present disclosure are directed to reducing the strain in at least a portion of the bulk silicon region by recessing the trench liner prior to oxidation, such as by performing hydrogen fluoride wet etching. This may provide room for the silicon to laterally expand during oxidation. The trench liner may be recessed by various amounts, such as to approximately the bottom of the hard mask layer, or approximately halfway to the bottom of the hard mask layer, or anywhere in between. The trench liner may even be recessed more deeply than the bottom of the hard mask layer, such as down to or below the upper surface of the upper silicon layer of the surrounding silicon-on-insulator (SOI) wafer.

These and other aspects of the disclosure will be apparent upon consideration of the following detailed description of illustrative embodiments.

### BRIEF DESCRIPTION OF THE DRAWINGS

A more complete understanding of the present invention and the advantages thereof may be acquired by referring to the following description in consideration of the accompanying drawings, in which like reference numbers indicate like features, and wherein:

FIGS. 1-6 and 9-14 are side cut-away views of a semiconductor device during various successive steps of an illustrative manufacturing process.

FIGS. 7 and 8 are side cut-away views of a semiconductor device during various steps of a conventional manufacturing process resulting in crystal defects in a HOT epitaxially-grown silicon region.

### DETAILED DESCRIPTION OF ILLUSTRATIVE EMBODIMENTS

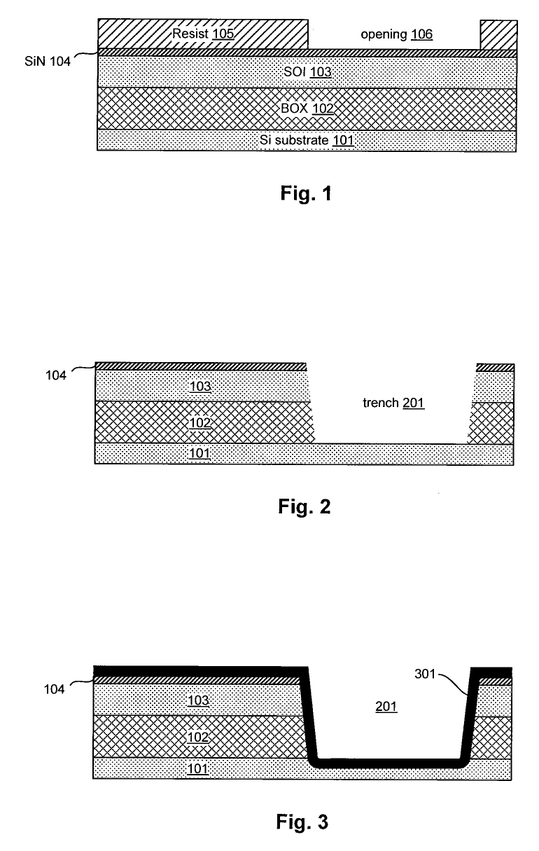

FIGS. 1-6 and 9-14 are side cut-away views of a semiconductor device during various successive steps of an illustrative manufacturing process. Referring to FIG. 1, a silicon-on-insulator (SOI) wafer may be provided that includes a lower silicon layer 101, an insulating layer such as a buried oxide layer (BOX) 102, and an upper silicon layer 103 disposed on buried oxide layer 102. These types of SOI wafers are commercially available. The SOI wafer may be provided such that upper silicon layer 103 has a particular surface orientation, such as (100) or (110). A hard mask layer 104, such as silicon nitride (SiN), may be formed on upper silicon layer 103.

To create a hybrid orientation technique (HOT) bulk silicon region, a trench is formed. In this example, a photo-resist layer 105 is be formed on hard mask layer 104 and selectively removed using conventional lithographic techniques to form an opening 106 in resist layer 105.

Next, referring to FIG. 2, a trench 201 is etched in the SOI wafer. Trench 201 may extend at least down to lower silicon layer 101, and is preferably large enough to contain a field-effect transistor (FET). Then, photo-resist layer 105 is removed.

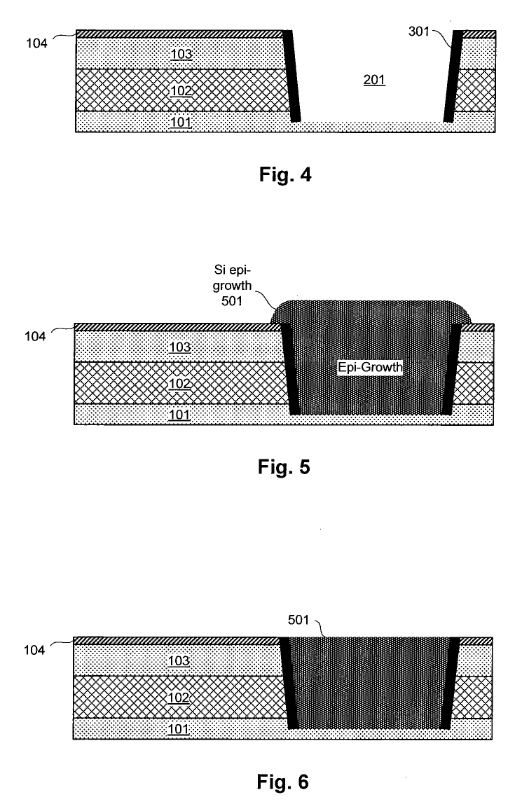

Next, referring to FIG. 3, a layer 301 of oxide (e.g., silicon oxide), nitride (e.g., silicon nitride), or another material, is deposited over the exposed surface of the semiconductor device including trench 201. The horizontal portions of layer 301 are then removed in a conventional manner, such as by anisotropic etching, as shown in FIG. 4. This results in layer 301 acting as a trench liner remaining on the vertical sidewalls of trench 201.

Next, a bulk silicon region 501 is epitaxially grown in trench 201 on the exposed surface of lower silicon layer 101. With minor exceptions such as where bulk silicon region 501 extends out of trench 201 onto hard mask layer 104, bulk silicon region 501 is a substantially mono-crystalline silicon structure. Due to the inherent nature of the epitaxial growth process, the bulk silicon region 501 will have the same crystalline orientation as lower silicon layer 101. Thus, bulk silicon region 501 may have a surface orientation different from the surface orientation of upper silicon layer 103, and the same surface orientation as lower silicon layer 101. For instance, where the surface orientation of upper silicon layer 103 is (100) and the surface orientation of lower silicon layer 101 is (110), the surface orientation of bulk silicon region 501 would be (110). In such a case, one would typically locate an NFET on and in upper silicon layer 103 of the SOI region and a PFET on and in bulk silicon region 501. Or, where the surface orientation of upper silicon layer 103 is (110) and the surface orientation of lower silicon layer 101 is (100), the surface orientation of bulk silicon region 501 would be (100). In this latter case, one would typically locate a PFET on and in upper silicon layer 103 of the SOI region and an NFET on and in bulk silicon region 501.

In the present example, trench 201 is shown in this example to have a bottom surface disposed within lower silicon layer 101. However, trench 201 may extend even further downward, such as to yet another silicon layer (not shown) below lower silicon layer 101. In such a case, bulk silicon region 501 would have the same crystalline orientation as whatever silicon layer is exposed at the bottom of trench 201.

As can be seen in FIG. 5, bulk silicon region 501 is grown so as to over-grow out of trench 201. This helps to ensure that trench 201 is completely filled with silicon and to allow for a flat upper surface to the silicon to be formed by removing the overgrowth. To form the flat upper surface, as shown in FIG. 6, the upper portion of bulk silicon region 501 is removed, such as by chemical-mechanical polishing (CMP). This results in the upper surface of bulk silicon region 501 being lowered and flattened such that it is substantially coplanar with the upper surface of hard mask layer 104.

FIGS. 7 and 8 show what would happen next in the process if conventional steps were taken, thus resulting in undesirable crystal defects in bulk silicon region 501. Referring to FIG. 7, the upper surface of bulk silicon region 501 is oxidized, thereby resulting in a silicon oxide layer 701 being formed. Because silicon expands in volume when oxidized, silicon oxide layer 701 expands upward. However, due to the existence of sidewall liner 301, silicon oxide layer 701 cannot easily expand laterally. Thus, an enormous amount of stress is induced in silicon oxide layer 701. This stress is transferred into the upper surface of non-oxidized crystalline bulk silicon region 501, resulting in crystal defects such as crystal defect 702. As shown in FIG. 8, silicon oxide layer 701 is then removed.

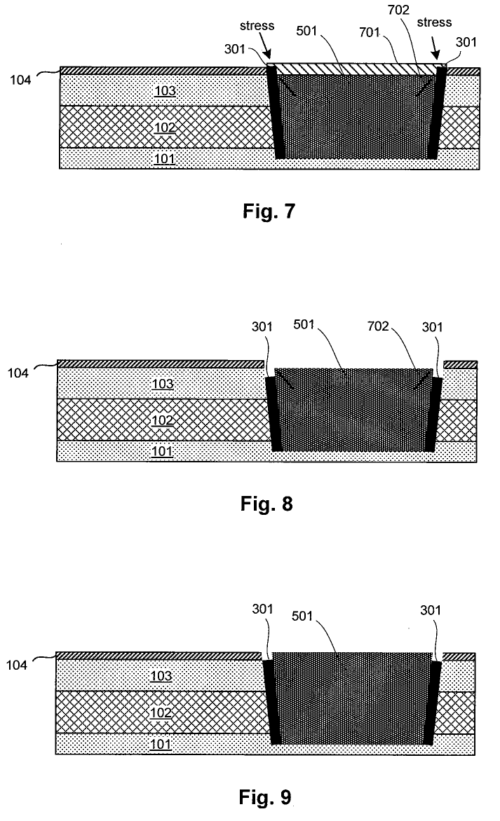

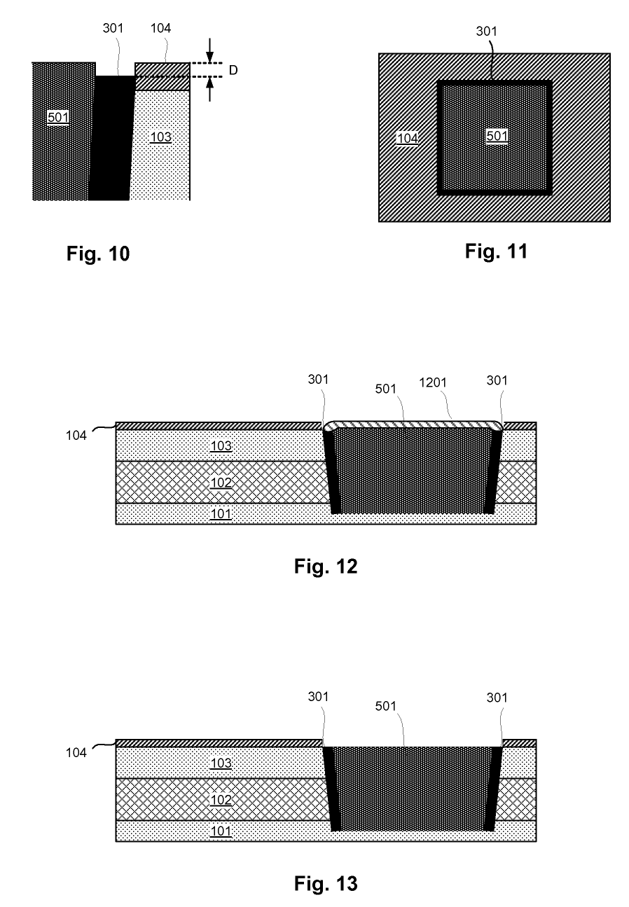

To reduce or even avoid crystal defects such as crystal defect 702, the following illustrative steps may be taken, as described with reference to FIGS. 9-12. Referring first to FIG. 9, an upper portion of sidewall liner 301 is removed, such that sidewall liner 301 is recessed relative to the surrounding upper surfaces. Referring to the detailed view of FIG. 10, sidewall liner 301 may be recessed by any distance D, where D is measured in a direction normal to the upper surface of the semiconductor device. For example, D may be one-half the thickness of hard mask layer 301, in the range of about one-half the thickness of hard mask layer 301 to about the full thickness of hard mask layer 301, or more. As also shown in the plan view of FIG. 11, sidewall liner 301 encircles bulk silicon region 501, and the recess may also be performed on the entire upper surface of sidewall liner 301 surrounding bulk silicon region 501 (i.e., the left, top, right, and bottom portions of sidewall liner 301 in the plan view of FIG. 11). Alternatively, only a portion of the upper surface of sidewall liner 301 may be recessed, such as on only two opposing sides of bulk silicon region 501 (i.e., either the left and right portions in the plan view of FIG. 11 or the top and bottom portions in the plan view of FIG. 11).

By removing some or all of the upper portion of sidewall liner 301, this provides lateral room for the upper portion of bulk silicon region 501 to expand during oxidation. Thus, as shown in FIG. 12, an upper portion of bulk silicon region 501 may now be oxidized, resulting in silicon oxide layer 1201. Because of the recess of sidewall liner 301, silicon oxide layer 1201 can expand laterally in addition to vertically. This reduces or even eliminates strain that would otherwise have been caused by the silicon oxide layer 1201 being restricted from lateral growth. Accordingly, crystal defects that would otherwise have been generated may be reduced or even avoided altogether.

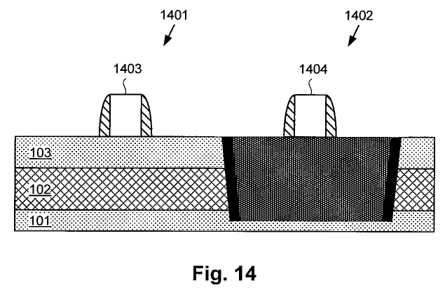

After silicon oxide layer 1201 is created, it may then be removed, as shown in FIG. 13. Then, one or more transistors and/or other circuit elements may be created in a conventional manner. For instance, as shown in FIG. 14, a first FET 1401 is created in and on bulk silicon region 501, and a second different type of FET 1402 is created in and on upper silicon layer 103 in the SOI region. As is conventional, FET 1401 and FET 1402 may each have a conductive gate 1403, 1404, respectively (e.g., polysilicon, also known as polycrystalline silicon) disposed over its respective silicon layer 103, 501, separated by a thin gate oxide or other insulating layer (not shown). In addition, source/drain regions (not shown) may be embedded in the respective silicon layer 103, 501, with a transistor channel defined between each source/drain pair. Each transistor gate 1403, 1404 may also have insulating sidewall spacers on opposing sides of the gate and may be completely covered by another insulating layer such as a silicon nitride layer and/or an inter-layer dielectric.

Thus, a method of manufacturing a semiconductor device, as well as the semiconductor device itself, has been disclosed, that may reduce the strain in at least a portion of a bulk silicon region by recessing a trench liner prior to oxidation.

1. A method for manufacturing a semiconductor device, comprising:
providing a structure including a first silicon layer disposed on an insulating layer, wherein the insulating layer is further disposed on a second silicon layer;
forming a trench extending completely through the first silicon layer and the insulating layer;
forming a liner on sidewalls of the trench, wherein a bottom of the trench is formed from an exposed portion of the second silicon layer;
epitaxially growing silicon on the exposed portion of the second silicon layer;
after the step of epitaxially growing, removing a first portion of the liner from the sidewalls of the trench such that a second portion of the liner remains; and
after the step of removing, oxidizing an exposed portion of the epitaxially grown silicon while the second portion of the liner remains.

2. The method of claim 1, further including removing the oxidized portion of the epitaxially grown silicon.

3. The method of claim 1, wherein the step of removing the portion of the liner includes performing wet etching of the liner using hydrogen fluoride.

4. The method of claim 1, wherein the liner is silicon oxide.

5. The method of claim 1, further including:
forming a silicon nitride layer on the first silicon layer; and
removing a portion of the silicon nitride layer, wherein the step of forming the trench includes forming the trench at a location of the portion of the silicon nitride layer that has been removed.

6. The method of claim 5, wherein the step of forming the liner includes forming the liner on the bottom of the trench and on the silicon nitride layer, and subsequently performing anisotropic etching to remove the liner from the bottom of the trench and from the silicon nitride layer.

7. The method of claim 5, wherein the step of removing the portion of the liner includes removing the portion of the liner such that the liner extends no higher than a lower surface of the silicon nitride layer.

8. The method of claim 5, wherein the step of removing the first portion of the liner includes removing the first portion of the liner such that an upper surface of the second portion of the liner is at a location between a lower surface of the silicon nitride layer and an upper surface of the silicon nitride layer.

9. The method of claim 1, further including removing a portion of the epitaxially-grown silicon by chemical-mechanical polishing before the step of removing the portion of the liner.

10. The method of claim 1, further including forming a first field-effect transistor in and on the first silicon layer and a second field-effect transistor in and on the epitaxially grown silicon.

11. The method of claim 1, wherein the insulating layer is an oxide.

12. A method for manufacturing a semiconductor device, comprising:
providing a structure including a first silicon layer disposed on an insulating layer, wherein the insulating layer is further disposed on a second silicon layer;
forming a trench extending completely through the first silicon layer and the insulating layer;
forming a liner on sidewalls of the trench;
after the step of forming the liner, forming a third silicon layer in the trench;
after the step of forming the third silicon layer, recessing the liner such that a portion of the liner remains; and
after the step of recessing, oxidizing an exposed portion of the third silicon layer while the portion of the liner remains.

13. The method of claim 12, further including performing chemical-mechanical polishing of the third silicon layer.

14. The method of claim 13, further including forming a silicon nitride layer on the first silicon layer, wherein the step of recessing and the step of chemical-mechanical processing is each performed while the silicon nitride layer is disposed on the first silicon layer.

15. The method of claim 14, wherein the step of forming the liner includes forming the liner on a bottom of the trench and on the silicon nitride layer and subsequently performing anisotropic etching to remove the liner from the bottom of the trench and from the silicon nitride layer.

16. The method of claim 12, wherein the liner is silicon oxide.

17. The method of claim 12, wherein the insulating layer is an oxide.

18. The method of claim 12, wherein the step of recessing includes performing wet etching of the liner.

19. The method of claim 12, wherein the step of forming the third silicon layer includes epitaxially growing the second silicon layer.

20. The method of claim 12, wherein the step of forming the third silicon layer includes completely filling the trench with the second silicon layer.

21. The method of claim 14, wherein an upper surface of the portion of the liner that remains is at a location between a lower surface of the silicon nitride layer and an upper surface of the silicon nitride layer.

22. The method of claim 1, wherein oxidizing includes oxidizing an upper surface and a portion of a side surface of the epitaxially grown silicon while the second portion of the liner remains.

23. The method of claim 12, wherein oxidizing includes oxidizing an upper surface and a portion of a side surface of the third silicon layer while the portion of the liner remains.
